(19) United States
(12) Patent Application Publication
(10) Pub. No.: US 2008/0009095 A1
(43) Pub. Date: Jan. 10, 2008

(54) Advanced Thin Flexible Microelectronic Assemblies and Methods for Making Same

(75) Inventors: Harry K. Charles JR., Laurel, MD (US); Charles V. Banda, Ellicott City, MD (US); Arthur S. Francomacaro, Eldersburg, MD (US); Allen C. Keeney, Upperco, MD (US); Seppo J. Lehtonen, Columbia, MD (US)

Correspondence Address: THE JOHNS HOPKINS UNIVERSITYAPPLIED PHYSICS LABORA;OFFICE OF PATENT COUNSEL, 11100 JOHNS HOPKINS ROAD, MAIL STOP 7-156, LAUREL, MD, 20723-6099, US

(73) Assignees: THE JOHNS HOPKINS UNIVERSITY, BALTIMORE, MD (US); The United States of America as represented by the National Security Agency, Washington, DC (US)

(21) Appl. No.: 11/756,816

(22) Filed: Jun. 1, 2007

Related U.S. Application Data
(60) Provisional application No. 60/809,874, filed on Jun. 1, 2006.

(51) Int. Cl. H01L 21/70

(52) U.S. Cl. 438/107; 257/E21.531

(57) ABSTRACT

A thin, flexible microelectronic assembly using thinned die (5-10 microns and lower) produced by growing a 1 μm-10 μm silicon epitaxial (Epi) layer on an oxidized silicon carrier. The integrated circuit process takes place in the standard manner in the Epi layer. The oxide layer and the silicon carrier serve as the backside handle. Once processed, the wafer can be bumped and singulated just like a normal chip without the need for the extra handle attachment processes or the backside thinning operation. Once the integrated circuits are flipped and solder reflowed to a substrate, the handle can be removed by etching the oxide. In one assembly embodiment, wells are etched in the flexible circuit board material to allow the interconnect to be recessed below the circuit board surface. An adhesive can then be placed on the board surface, locking the die to the flexible substrate. Alternatively, a nanowire interposer can be sandwiched between a bumped multilayer substrate and a bumped thin die. Further, indium bumps can be substituted for solder bumps to provide a more flexible assembly.

### CROSS REFERENCE TO RELATED APPLICATIONS

This application claims the benefit of prior filed, co-pending U.S. provisional application: Ser. No. 60/809,874, filed on Jun. 1, 2006, which is incorporated herein by reference in its entirety.

### BACKGROUND OF THE INVENTION

1. Field of the Invention

The present invention relates generally to microelectronic packaging and, more particularly, to advanced thin flexible microelectronic assemblies and methods for making such assemblies.

2. Description of the Related Art

Conventional microelectronic packaging involves the mounting of standard integrated circuit die in either a face-up (wirebonded) or a face-down (flip chip) configuration as shown in FIGS. 1A and 1B, respectively. Techniques for implementing such configurations are well known and have been reported in the literature for almost 50 years.

Initially, such mounting took place on substrates with matched coefficients of thermal expansion (CTE) such as flip chip on ceramic. As the use of inorganic substrates waned, mainly due to cost, the need for new assembly methods and processes arose, including the ability to wirebond to soft organic circuit boards and the use of underfills to improve the reliability of flip chip assemblies (low CTE chip mounted to high CTE board). The use of underfill is shown schematically in FIG. 1B.

As noted above, as technology has advanced, the standard glass fiber reinforced organic board has given way to unreinforced organic circuit boards, again causing reliability concerns. Most packaging structures involving unreinforced organic circuit boards involve some form of compliant layer or compliant underfill.

Growing economic and application pressures have also forced microelectronic packages and assemblies to become smaller, not just in footprint, but also in height. Some packages now contain multiple die stacked in the height of a single chip. Currently, to accomplish this, die must be thinned using a rather laborious grinding, polishing, and etching process. Encapsulation and underfilling still remain processes of critical importance.

Die thinning in industry has traditionally been confined to thicknesses on the order of 100 μm or greater. This can be accomplished by mounting the wafer face down on a platen and performing grinding and polishing operations, and then releasing the free standing wafer to conventional processing, such as solder bumping and singulation.

Thinning much below 100 μm has not been reported outside of government laboratories; see, for example, U.S. Pat. No. 6,013,534 which is incorporated by reference herein in its entirety. In thinning below 100 μm, the die or wafer must be mounted to a carrier, more commonly called a frontside handle. After handle attachment, the thinned die is produced by grinding, lapping and polishing, and chemical etching. Nominal thicknesses of 25 μm have been achieved. The use of the handle is necessary because the thinned die structure is extremely fragile.

After thinning, the dies are either 1) attached to a substrate in a conventional faceup manner, after which the frontside carrier is released, or 2) attached to a backside handle after which the frontside handle is released. In the faceup configuration, the thinned die are wirebonded to complete the circuit. With a backside handle in place, the die or wafer can be bumped, singulated, and assembled in a flip chip configuration using the backside handle to hold the fragile die. After assembly, the backside handle is also released.

Because of the stresses involved in the conventional die thinning processes (grinding, lapping and polishing) it is unlikely that die thinning much below 25 μm will be possible. Therefore, what is needed are methods to produce thinned die down to a thickness of one micron and routinely down to 5-10 microns in order to make truly flexible chip assemblies.

### SUMMARY OF THE INVENTION

Therefore, the present invention has been made in view of the above problems, and it is an objective of the present invention to provide ultra thin (nominally 30-75 microns) assemblies suitable for a wide range of conventional circuit applications, as well as appliqués to curved surfaces with small radii.

The invention includes a method for thinning a die comprising the steps of: depositing a sacrificial layer on a silicon carrier; growing a silicon epitaxial layer on the sacrificial layer; creating a plurality of integrated circuits in the silicon epitaxial layer to form the die; singulating the die; flipping and connecting the die to a substrate; and removing the silicon carrier by removing the sacrificial layer.

The invention further includes a method for assembling a die to a multilayer interconnect substrate comprising the steps of: etching a plurality of wells in the multilayer interconnect substrate; flipping the die; and adhering the die to the multilayer interconnect substrate.

The invention further includes a method for assembling a die to a multilayer interconnect substrate comprising the steps of: bumping the multilayer interconnect substrate; bumping the die; flipping the die; and inserting a nanowire interposer between the bumped multilayer interconnect substrate and the bumped die.

The invention further includes a method for assembling a die to a multilayer interconnect substrate comprising the steps of: bumping the die with bumps comprising indium; flipping the die; and attaching the die to the multilayer interconnect substrate comprises a flexible, thin-film circuit board.

### BRIEF DESCRIPTION OF THE DRAWINGS

These and other objects, features and advantages of the invention will be apparent from a consideration of the following Detailed Description Of The Invention considered in conjunction with the drawing Figures, in which:

FIG. 1, consisting of FIGS. 1A and 1B, illustrates stand alone conventional substrates/chip assemblies in a face up (wirebonded) or a face down (flip chip) configuration, respectively.

FIG. 2, consisting of FIGS. 2A, 2B, and 2C, illustrates the method of the invention for producing ultra thin die/integrated circuits by illustrating an example starting configuration (FIG. 2A), the starting configuration after fabrication of integrated circuits in an epitaxial layer (FIG. 2B), and the die after singulation (FIG. 2C).

FIG. 3 illustrates a microelectronic assembly with a well etched in a flexible circuit board material allowing the interconnect to be recessed below the circuit board surface.

FIG. 4 illustrates a microlectronic assembly with a nanowire interposer.

FIG. 5 illustrates a microelectronic assembly and clamping techniques for use with a nanowire interposer.

FIG. 6 illustrates a microlectronic assembly wherein the solder bumps are replaced with indium bumps to form a highly flexible assembly.

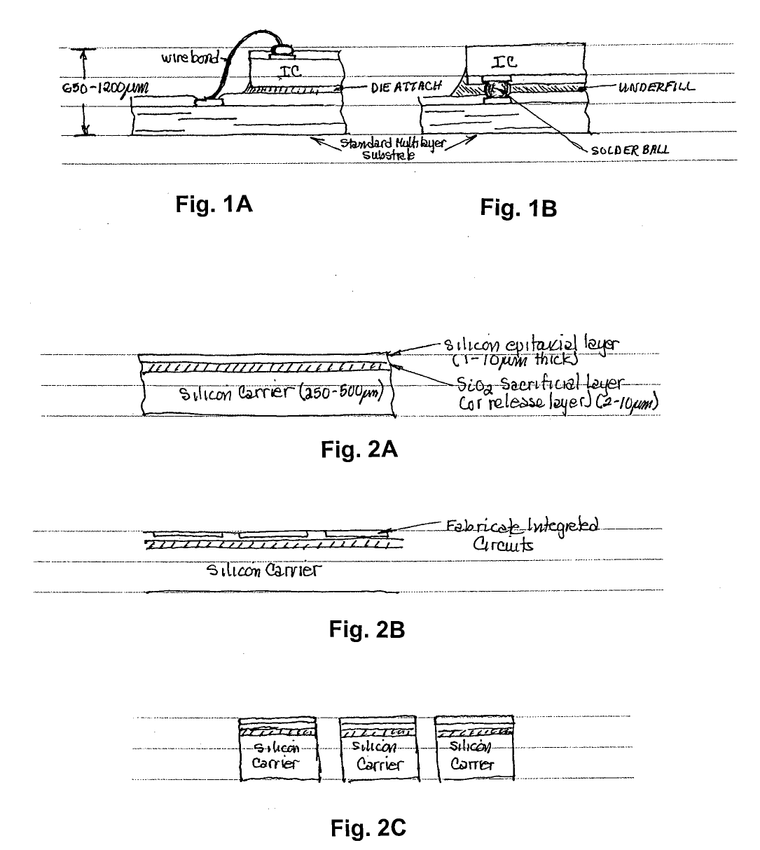

### DETAILED DESCRIPTION

The method of the invention is capable of producing thinned die down to a thickness of 1 μm and routinely at the 5-10 μm level. In this technique, as shown in FIG. 2A, the die must be fabricated on a silicon on isulator wafer or carrier.

As also shown in FIG. 2A, a silicon epitaxial (Epi) layer of, for example, 1-10 μm in thickness is grown or deposited on a sacrificial or release layer of, for example, a 2-10 μm layer of an adhesive or oxide or nitride. By way of example only, FIG. 2A illustrates a deposit/growth of silicon dioxide (SiO₂) on a silicon wafer or carrier. The integrated circuit process then takes place in the standard manner with the creation of integrated circuits in the Epi layer (FIG. 2B). The sacrificial layer of, e.g., SiO₂ (oxide layer) and the silicon carrier serve as a backside handle. Once the integrated circuit creation process is completed, the Epi can be bumped, as appropriate, while still attached to the oxide layer-carrier. The die can then be singulated as shown in FIG. 2C just like a normal chip without the need for the extra handle attachment processes or the backside thinning operation because the oxide layer-carrier is the backside handle.

After the integrated circuits are “flipped” and solder reflowed to a substrate, the oxide layer-carrier handle can be removed by etching (or dissolving in the case of an adhesive) the oxide layer. Underfill may be necessary to ensure that the extremely thin and fragile die are supported and the solderballs are protected during the etch. Solderballs are only an example of the type of interconnect that could be placed on the die. Solder pillars or solder coated micro or nanowires could also be used.

Another aspect of the invention comprises novel methods to achieve the intimate contact between the die and substrate or interposer required for system reliability and low ultimate system height. One embodiment consists of depositing and patterning the multilayer interconnect substrate directly on top of the die forming an integrated substrate system (multiple dies) which is of minimal height (≦35 μm). However, the issues of repair, non-working die, etc., may make this embodiment less economically attractive unless individual die yields are high.

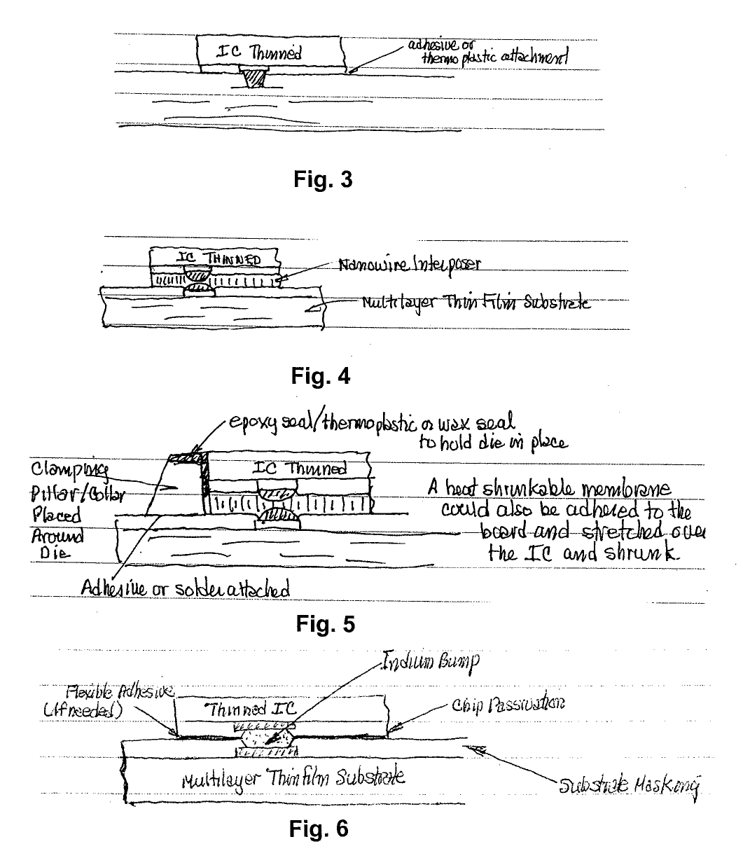

Another embodiment is shown in FIG. 3 in which wells are etched in a flexible circuit board material (substrate) to allow the interconnect to be recessed below the circuit board surface. An adhesive can then be placed on the board surface, locking the die to the flexible substrate after the die is flipped.

Both the thinned die and flexible substrate are attached to handles during the attachment process which can then be dissolved away post-assembly. This method yields assemblies with a profile height of 60 μm for die thickness on the order 25 μm and 45 μm if the 25 μm die are replaced by a 10 μm epitaxial layer die as described above. However, once attached to the substrate, the assembly cannot be repaired.

If a repairable assembly embodiment is desired, then a nanowire interposer, as shown schematically in FIG. 4 can be used. The nanowire interposer is sandwiched between a bumped multilayer substrate and a bumped thin die after the die is flipped. The nanowire interposer is composed of uniformly spaced and sized nanowires in an organic resin. The nanowire interposer can also be patterned to only allow conductive nanowires to be grown in the vicinity of the contacts.

The organic resin can be a thermoplastic, thus deforming at higher temperature and providing both contact and adhesion upon cooling. Alternatively, the resin can be elastomeric in nature, thus requiring a clamp mechanism to ensure viable electrical contact. Even with clamping requirements, assemblies below 50 μm in height can be attained.

Some techniques for clamping are shown in FIG. 5. These techniques can include by way of example: 1) use of an epoxy, thermoplastic or wax seal to hold the die in place; 2) use of a claimping pillar or collar placed around the die; or 3) use of a heat shrinkable membrane adhered to the substrate, stretched over the die and then shrunk.

Another interconnect embodiment is shown in FIG. 6. In this method, the solder bumps are replaced with soft, flexible indium bumps. The die is then flipped. Such assemblies may obviate the need for the adhesive attachment between the die and the flexible multilayer substrate. Given the flexibility of indium at low temperatures, such an assembly may be useful for cryogenic applications.

The flexible substrate/circuit board used in the embodiments described above consists of multi-layer, thin-film type construction using polyimide dielectric layers and copper metallization. The circuit board/substrate ultimately will be separated from its fabrication support (carrier) and, thus, will be free standing and flexible. This separation is accomplished either by etching away the carrier or by the use of a sacrificial layer similar to that used for the integrated circuit described above. This substrate separation from the support may be done either before or after assembly. These super flexible substrates will contain several conducting layers (e.g., 4-6) and be less than or equal to 35 μm in thickness.

While various embodiments have been described above, it should be understood that they have been presented by way of example only, and not limitation. Thus, the breadth and scope of a preferred embodiment should not be limited by any of the above described exemplary embodiments, but should be defined only in accordance with the following claims and their equivalents.

What is claimed is:

1. A method for thinning a die comprising the steps of:
depositing a sacrificial layer on a silicon carrier;
growing a silicon epitaxial layer on the sacrificial layer;
creating a plurality of integrated circuits in the silicon epitaxial layer to form the die;
singulating the die;
flipping and connecting the die to a substrate; and
removing the silicon carrier by removing the sacrificial layer.

2. The method as recited in claim 1, further comprising the step of bumping the die before the singulating step.

3. The method as recited in claim 1, wherein the sacrificial layer comprises one of an oxide layer and a nitride layer.

4. The method as recited in claim 1, wherein the sacrificial layer comprises silicon dioxide.

5. A method for assembling a die to a multilayer interconnect substrate comprising the steps of:
depositing the multilayer interconnect substrate on the die; and
patterning the multilayer interconnect substrate.

6. A method for assembling a die to a multilayer interconnect substrate comprising the steps of:
etching a plurality of wells in the multilayer interconnect substrate;
flipping the die; and
adhering the die to the multilayer interconnect substrate.

7. A method for assembling a die to a multilayer interconnect substrate comprising the steps of:
bumping the multilayer interconnect substrate;
bumping the die;
flipping the die; and
inserting a nanowire interposer between the bumped multilayer interconnect substrate and the bumped die.

8. The method as recited in claim 7, wherein the nanowire interpose comprises a plurality of uniformly spaced and sized nanowires in an organic resin.

9. The method as recited in claim 8, wherein the resin comprises one of a thermoplastic and an elastomeric.

10. The method as recited in claim 7, wherein the nanowire interposer is patterned to allow only conductive nanowires to be grown in the vicinity of electrical contacts.

11. A method for assembling a die to a multilayer interconnect substrate comprising the steps of:
bumping the die with bumps comprising indium;
flipping the die; and
attaching the die to the multilayer interconnect substrate.

12. The method of claims 5, 6, 7, or 11 wherein the multilayer interconnect substrate comprises a flexible, thin-film circuit board.
